(19) United States
(12) Patent Application Publication
(10) Pub. No.: US 2006/0267059 A1
(43) Pub. Date: Nov. 30, 2006

(54) Peripheral circuit architecture for array memory

(75) Inventors: Chuan-Ying Yu, Hsinchu City (TW); Chun-Hsiung Hung, Taichung City (TW); Su-Chueh Lo, Maioli County (TW); Nai-Ping Kuo, Hsinchu City (TW); Ken-Hui Chen, Taichung County (TW)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: Macronix International Co., Ltd.

(21) Appl. No.: 11/137,098

(22) Filed: May 25, 2005

(51) Int. Cl. H01L 29/94

(52) U.S. Cl. 257/296

(57) ABSTRACT

A wordline driver cell, coupled to at least one wordline, includes at least one diffusion region and at least one wordline driver semiconductor switching device formed in the at least one diffusion region. The at least one wordline driver semiconductor switching device has a channel width that is arranged perpendicular to a longitudinal axis of the at least one wordline.

### BACKGROUND OF THE INVENTION

The invention relates to memory devices and more particularly to peripheral circuits that address memory arrays.

High density information storage is increasingly enabled by memory arrays based on semiconductor, magnetic, or ferroelectric memory cells. Generally, these arrays are arranged as two dimensional arrays of storage cells, each cell addressable based on a mutually-orthogonal set of conductive wires, generally termed bitlines and wordlines. Wordlines can be used in semiconductor-based memories, for example, dynamic random access memory (DRAM), electrically erasable programmable read-only memory (EEPROM), or FLASH memory, to activate a transistor gate of a memory cell to read and write information to the memory cell.

As the size of memory cells shrink due to the ability to fabricate smaller dimensions of transistors and wordlines, the overall size of memory arrays is also shrinking. For example, DRAM cells are approaching 150 nanometers (nm) in pitch and 0.04 micrometers² (μm²) in area. Accordingly, a 2-Gigabit (GB) memory occupies an area of a square chip of only about 12 millimeters (mm) on edge. However, as the area of memory arrays shrink, the area occupied by peripheral circuits used to write to and access information from the memory arrays, can occupy an increasingly larger fraction of total chip area. For example, wordline driver circuits used to charge the wordlines are arranged in peripheral regions of memory arrays, in close proximity to ends of wordlines that are to receive the voltage. These circuits have transistors that are typically arranged in a much less dense fashion that in the memory arrays.

FIG. 1 illustrates a schematic electrical diagram of a conventional wordline driver circuit 100, illustrating a p-type field effect transistor (pFET) 102 and a pair of n-type field effect transistors (nFETs) 104 and 106. A source/drain region in each of pFET 102, and nFETs 104 and 106 is connected to driven wordline 108. In addition, a source/drain region of pFET 102 and nFET 104 is connected to a global wordline power line 110 that typically can be used to supply voltage to other wordlines (not shown).

FIG. 2 depicts a plan view of a conventional wordline driver circuit arrangement 200. Arrangement 200 contains a set of four wordline driver circuits 202, 204, 206, 208, each circuit arranged to drive a separate wordline 210. The arrangement of wordline driver circuits 202-208 each corresponds to the schematic wordline driver circuit 100 of FIG. 1. Portions of wordline driver circuits 202-208 are indicated by the position of transistors forming the driver circuits. The transistor gates of the transistors are arranged so that the gate width (typically the longer dimension of a gate) runs parallel to the wordlines 210. For the sake of clarity, each transistor is indicated by the respective transistor gate. Individual pFETs of respective circuits 202-208 are labeled 202a-208a. Similarly, first and second nFETs of respective circuits 202-208 are labeled 202b-208b and 202c-208c, respectively. Wordline driver circuits 202-208 are part of a wordline driver circuit cell 220 that is used to drive four wordlines 210 in array region 221, beginning with the top wordline in FIG. 2, and including every other wordline. Thus, a top wordline, 3rd from top, 5th from top, and 7th from top are driven by cell 220, using metal lines 224. Wordline driver cell 220 further includes four n-type diffusion regions 202d, 204d, 206d, and 208d that contain respective pFETs 202a-208a. Also included in cell 220 are a first set of p-type diffusion regions 202e, 204e, 206e, and 208e that contain respective transistors 202b-208b. Finally, cell 220 contains a second set of p-type diffusion regions 202f, 204f, 206f, and 208f that contain respective transistors 202c-208c. A wordline driver cell 230 arranged just below cell 220 is used to drive other wordlines lying below the top wordlines in FIG. 2.

In the arrangement indicated in FIG. 2, each wordline driver transistor is formed in a separate diffusion region. One problem with the arrangement indicated is that the layout width LW of wordline driver cells 220 and 230 must be sufficiently large to accommodate a series of 12 diffusion regions (4 n-type and 8 p-type) arranged in a linear fashion and extending outwardly from the array periphery region. In addition, each diffusion region must have a dimension that is sufficiently large to accommodate the width of the transistor gate formed on the respective diffusion region. As is well known to those skilled in the art, the speed of a transistor is proportional to the width of the transistor channel, which is defined as a dimension that is generally orthogonal to the direction of current flow across the transistor channel between source and drain regions, and corresponds to the portion of a transistor in which the gate overlaps the source/drain region. Thus, in FIG. 2, the channel width of pFET 208a corresponds to dimension Dn of n-type diffusion region 208d running parallel to wordlines 210. In order to achieve desired transistor speed, for example, Dn needs to be relatively larger. However, this requires LW to remain large. For example, for current generation circuits, Dn can be about 10 μm, so that the sum total of Dn's for n-type diffusion regions 202d-208d is about 40 μm. In the case of p-type diffusion regions, Dp in current technology can be in the range of 3.5 μm. Nevertheless, the total sum of Dp's in FIG. 2 for 8 diffusion regions would still equal about 28 μm. In addition, design rules require a spacing S between diffusion regions, where S may typically amount to about 1.1 μm in current technology. In the layout of FIG. 2, beginning at the periphery of array 221 and extending to the outer edge 229 of layout 200, there are ten successive regions 207 between nearest neighbor diffusion regions, meaning that the total of all spacings S of such regions is about 11 μm. Including smaller contributions from required diffusion-to-well separations and other rules, LW can equal almost 80 μm in current technology.

In addition, as array pitch shrinks, the relative contribution to total area for peripheral circuits such as driver cells 220 and 230 is likely to increase, as the latter do not have design rules as stringent as elements in the array.

### BRIEF SUMMARY OF THE INVENTION

Briefly stated, the present invention comprises a wordline driver cell coupled to at least one wordline. The wordline driver cell includes at least one diffusion region and at least one wordline driver semiconductor switching device formed in the at least one diffusion region. The at least one wordline driver semiconductor switching device has a channel width that is arranged perpendicular to a longitudinal axis of the at least one wordline.

The present invention also comprises a memory circuit architecture including a plurality of wordlines defining a longitudinal axis, an array of memory cells addressable by at least one of the plurality of wordlines and a plurality of wordline driver cells disposed along a peripheral region of the array of memory cells. Each of the plurality of wordline driver cells includes a plurality of diffusion regions that form a plurality of wordline driver semiconductor switching devices. Each of the semiconductor switching devices has a channel width, and each of the semiconductor switching devices is arranged so that its respective channel width is perpendicular to the longitudinal axis of the plurality of wordlines.

In another aspect, the present invention comprises a peripheral circuit architecture for a memory array having a plurality of wordlines. The peripheral circuit architecture includes a plurality of diffusion regions that form semiconductor switching devices, a plurality of wordline driver semiconductor switching devices and a plurality of electrical conductor lines. Each of the wordline driver semiconductor switching devices is formed in one of the diffusion regions and each of the wordline driver semiconductor switching devices has a respective channel width. Each of the electrical conductor lines electrically connects one or more of the plurality of wordline driver semiconductor switching devices to one of the plurality of wordlines in the memory array. The channel width of each of the wordline driver semiconductor switching devices is disposed substantially perpendicular to a longitudinal axis of at least one of the wordlines in the memory array.

In yet another aspect, the present invention comprises a wordline driver cell coupled to a plurality of wordlines. The wordline driver cell includes at least one p-type diffusion region arranged to extend outwardly from a portion of a peripheral region of a memory array and at least one n-type diffusion region arranged to extend outwardly from a portion of a peripheral region of a memory array. The wordline driver cell also includes at least one p-type wordline driver transistor having source/drain regions formed within the at least one n-type diffusion region and having a gate channel width arranged perpendicular to a longitudinal axis of the plurality of wordlines. The wordline driver cell also includes at least one n-type wordline driver transistor having source/drain regions formed within the at least one p-type diffusion region and having a gate channel width arranged perpendicular to the longitudinal axis of the plurality of wordlines. The wordline driver cell further includes at least one wordline driver circuit formed by coupling the p-type wordline driver transistor and the n-type wordline driver transistor to one of the plurality of wordlines coupled to the wordline driver cell.

### BRIEF DESCRIPTION OF THE SEVERAL VIEWS OF THE DRAWINGS

The foregoing summary, as well as the following detailed description of a preferred embodiment of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 is a schematic electrical circuit diagram illustrating a wordline driver circuit according to known art;

FIG. 2 depicts a plan view of a known wordline driver circuit architecture;

FIG. 3a depicts a plan view of a wordline driver circuit architecture according to one embodiment of the present invention;

FIG. 3b illustrates details of the architecture of FIG. 3a; and

FIG. 3c illustrates additional features of the architecture of FIG. 3a.

### DETAILED DESCRIPTION OF THE INVENTION

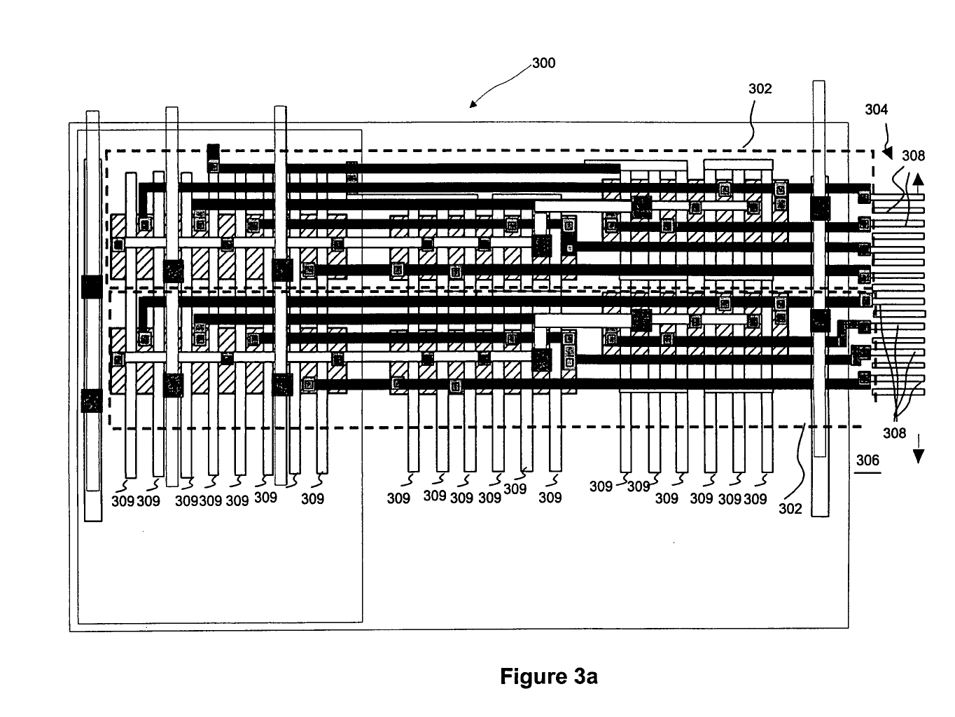

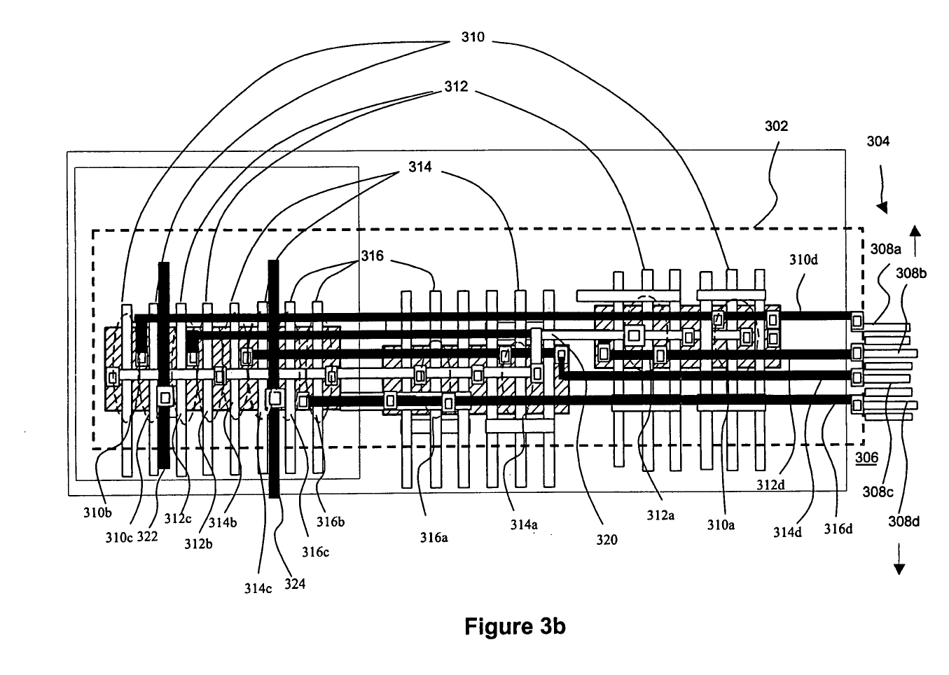

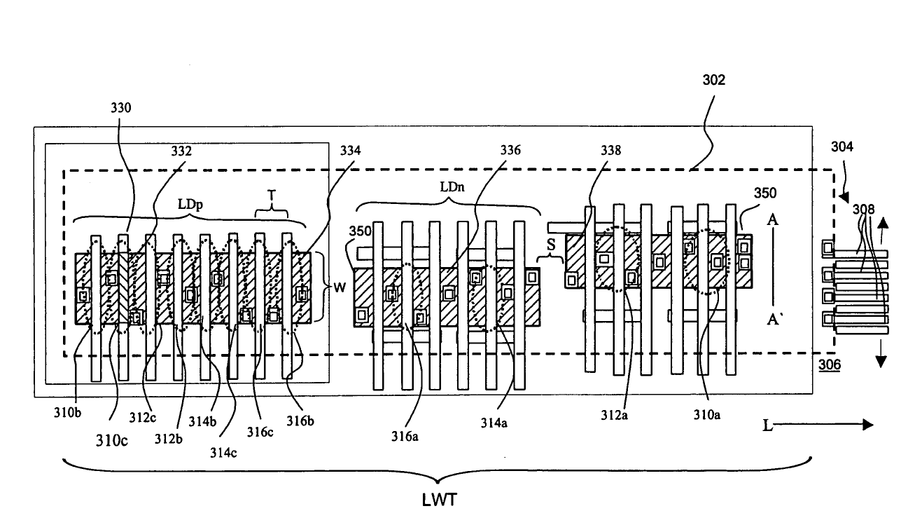

FIG. 3a illustrates a wordline circuit driver architecture 300 arranged in accordance with a preferred embodiment of the present invention. In this example, two substantially similar wordline driver cells 302 are depicted. Each cell 302 contains a series of four word line driver circuits (shown in more detail in FIG. 3b). Each cell is responsible for driving four different wordlines 308 arranged in array 304. As illustrated, transistor gate portions 309 are arranged so that the long direction of the gate (i.e., gate width or channel width) is perpendicular to the long direction of wordlines 308. In the illustrated embodiment, architecture 300 is replicated such that driver cells 302 are disposed along an entire length of array peripheral region 306, that extends along an entire edge of an array, where the edge runs perpendicular to the longitudinal axis of wordlines 308. Thus, architecture 300 can be a part of a peripheral circuit region that extends along one full edge of a memory array.

In addition, a similar peripheral circuit region can be disposed along an opposite edge of array 304. In this manner, two separate peripheral circuit regions (not shown) containing wordline driver circuits can be arranged on opposite sides of wordline array 304 near the ends of wordlines 308. Each separate peripheral circuit region will contain wordline driver circuits that contact every other wordline, with a stagger of one wordline between wordline driver circuits arranged on opposite ends of wordlines, so that every wordline is contacted by a driver circuit.

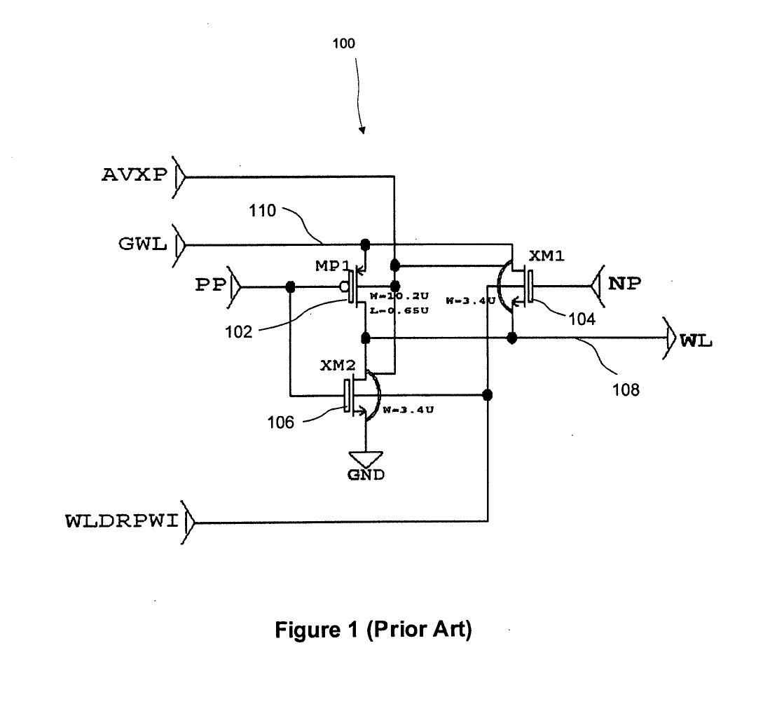

FIG. 3b illustrates details of a preferred wordline driver cell 302. Wordline driver cell 302 includes four wordline driver circuits 310, 312, 314, and 316. Each wordline driver circuit 310, 312, 314, 316 includes a p-type field effect transistor (pFET) 310a, 312a, 314a, 316a and two n-type field effect transistors (nFETs) 310b-310c, 312b-312c, 314b-314c, 316b-316c arranged to form electrical connections in a substantially similar fashion to that of the schematic electrical circuit diagram in FIG. 1.

For example, wordline driver circuit 310 contains pFET 310a and nFETs 310b, 310c. pFET 310a and nFET 310b are each connected by electrical conductor line or metal line 310d to wordline 308a, and are also each connected to global wordline power line 320. nFET 310c is connected to wordline 308a and to ground line 322. Each of wordline driver circuits 312, 314, and 316 has an analogous arrangement of transistors 312a-312c, 314a-314c and 316a-316c, respectively, that are used to drive respective wordlines 308b, 308c, and 308d. Thus, for example, wordline driver circuit 316 contains pFET 316a and nFETs 316b, 316c. pFET 316a and nFET 316b are each connected by electrical conductor line or metal line 316d to wordline 308d, and are also each connected to global wordline power line GWL 320. nFET 316c is connected to wordline 308d and to ground line 324.

FIG. 3c illustrates additional features of wordline driver cell architecture 300. In this case, metal lines or electrical connecting wordline driver transistors to respective wordlines are not shown to aid in clarity. In accordance with the arrangement illustrated in FIG. 3b, all transistor gates are arranged so that a transistor channel width forms in a direction A-A′ that is perpendicular to the longitudinal axis L of wordlines 308. Thus, gate 330 of wordline driver nFET transistor 310c has a longitudinal axis that runs perpendicular to direction L and forms a channel region 332 and within p-type diffusion region 334. When nFET transistor 310c is turned on, current flows across channel region 332 and under gate 330 in direction L. The channel width can be defined by the extent of overlap in the A-A′ direction of gate 330 with diffusion region 334. In the case of a simple linear gate, the channel width is simply equal to W.

In accordance with the peripheral circuit architecture illustrated in FIG. 3c, wordline driver cell 302 contains three diffusion regions: p-type region 334, and n-type regions 336 and 338. It will be apparent to those of ordinary skill in the art that p-type diffusion region 334 is used to form nFET transistors 310b-310c, 312b-312c, 314b-314c, 316b-316c by introducing n-type dopants therein. Similarly, n-type diffusion regions 336 and 338 are used to form pFET transistors 310a, 312a, 314a, 316a by introducing p-type dopants. As illustrated in FIG. 3c, a total of eight nFET transistors 310b-310c, 312b-312c, 314b-314c, 316b-316c are formed in the layout area defined by p-type diffusion region 334. As discussed above with respect to FIG. 3b, the transistors 310a-310c, 312a-312c, 314a-314c, 316a-316c form part of four wordline driver circuits 310, 312, 314, 316.

Thus, broadly speaking, the wordline driver cell 302 formed in accordance with the preferred embodiment of the present invention is coupled to at least one wordline 308. The wordline driver cell 302 includes at least one diffusion region 334, 336, 338 arranged to extend outwardly from a peripheral region of a memory array 304 and at least one wordline driver semiconductor switching device (e.g., a transistor) 310a-310c, 312a-312c, 316a-316c formed in the at least one diffusion region 334, 336, 338. The at least one wordline driver semiconductor switching device 310a-310c, 312a-312c, 316a-316c has a channel width W that is arranged perpendicular to a longitudinal axis L of the at least one wordline 308.

An advantage of orienting the gates of transistors 310b-c, 312b-c, 314b-c, and 316b-c so that the transistor channel width is perpendicular to the longitudinal axis direction L of wordlines 308, is that the transistors 310a-310c, 312a-312c, 316a-316c can be spaced very closely in the L direction at a distance T between successive transistors 310a-310c, 312a-312c, 316a-316c. This is because T is determined by design rules for placing nearest neighbor gate-level structures. In an exemplary embodiment, the transistor gates are fabricated from polysilicon according to known methods. In the case of polysilicon gates, design rules for minimum spacing between neighboring polysilicon features may be equal, for example, to a value of 2λ, where λ is the minimum design rule feature. For example, if a typical λ for present day peripheral circuit architecture is about 0.55 μm, the minimum polysilicon-to-polysilicon spacing can be about 1.1 μm. For a gate length of 0.55 μm (where the gate length is the typically shorter gate dimension that is defined in the same direction as current flow from source to drain), the total distance between centers of successive gates is thus 1.65 μm. In this case, in order to accommodate eight successive gates, and accounting for a polysilicon-to-diffusion edge ground rule (not shown), a total length LDp of diffusion region 334 is about 13.2 μm or so.

Similarly, a total length LDn for n-type diffusion regions 336 and 338 is determined by the number of polysilicon gates therein. In the example of FIG. 3c, two transistors are formed in each n-type diffusion region. Three parallel gate portions, in turn, are shown to be formed for each pFET transistor. Even so, the total width LDn of gate n-type diffusion regions 336 and 338, is about 10-11 μm each, when using the same design rule as for the nFETs. Additionally, for the case where pFETs are configured as simple, single gate portion transistors similar to the nFETs in region 334, LDn can be much smaller.

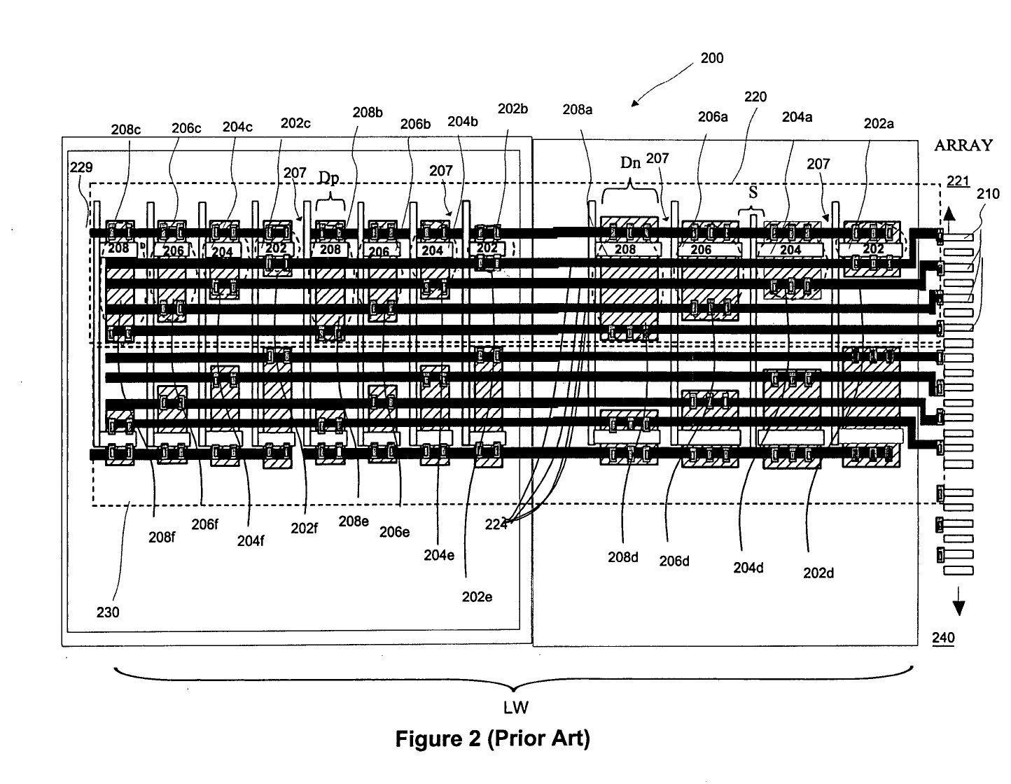

Finally, because cell 302 only contains three diffusion regions, the contribution to layout width from diffusion-to-diffusion design rules is small, as compared to that seen in conventional layout 200 of FIG. 2. In this case, only one region exists where spacing S is required, adding only about 1.1 μm in total width. In sum, total layout width LWT of cell 302 is about 40 μm for the same design rules employed in conventional architecture 200 of FIG. 2, where the layout width LW is about 80 μm. Thus, a reduction of about one half in layout width LW occupied by a wordline driver circuit is provided by the architecture of FIG. 3, in comparison with conventional wordline driver circuit architecture.

It is contemplated that n-type diffusion regions 336, 338 within each of the driver cells 302 are mutually spaced along a direction parallel to the wordlines according to a “diffusion-to-diffusion rule,” and p-type diffusion regions within each of the driver cells are spaced from an outer edge of an n-type diffusion region by a “sum-of-a-well rule” and two “diffusion-to-well rules.”

It is contemplated that each of the wordline driver cells 302 comprises two nearest neighbor n-type diffusion regions 336, 338, and that each n-type diffusion region 336, 338 is used to form two p-type transistors 310a, 312a, 314a, 316a of two respective wordline driver circuits 302. a mutual separation between adjacent n-type diffusion regions 336, 338 in a direction parallel to the wordlines 308 is defined by a “diffusion-to-diffusion ground rule.”

A further feature of the present invention, as illustrated in FIG. 3c is the use of a slight stagger between the position of a top edge 350 of neighboring n-type diffusion regions 336 and 338. By further providing a stagger in global wordline power line GWL 320, as shown in FIG. 3b, metal lines connected to wordlines 308 and contacting transistors in a first n-type diffusion region do not run over the other n-type diffusion region where contact is to be avoided. In addition, by providing a wider diffusion width W for p-type diffusion region 334, than for n-type diffusion regions 336 and 338, metal lines can be arranged for the most part in straight lines between wordlines 308 and contacted portions of the respective diffusion regions.

The foregoing disclosure of configurations of the present invention has been presented for purposes of illustration and description. It is not intended to be exhaustive or to limit the invention to the precise forms disclosed. Many variations and modifications of the configurations described herein will be apparent to one of ordinary skill in the art in light of the above disclosure. The scope of the invention is to be defined only by the claims appended hereto, and by their equivalents. For example, variations in which a wordline driver cell corresponds to more than or fewer than four wordline driver circuits are within the scope of the invention. In addition, the present invention is capable of being used in conjunction with any type of memory array having addressable memory arrays, such as Flash, Mask ROM, DRAM, EEPROM, FeRAM, and MRAM.

We claim:

1. A wordline driver cell coupled to at least one wordline, the wordline driver cell comprising:
at least one diffusion region; and
at least one wordline driver semiconductor switching device formed in the at least one diffusion region, the at least one wordline driver semiconductor switching device having a channel width that is arranged perpendicular to a longitudinal axis of the at least one wordline.

2. The wordline driver cell according to claim 1, wherein the wordline is coupled to at least one memory cell, the at least one memory cell being addressable by the at least one wordline.

3. The wordline driver cell according to claim 1, wherein the at least one wordline driver cell is disposed along a peripheral region of an array of memory cells.

4. The wordline driver cell according to claim 1, wherein the at least one diffusion region is arranged to extend outwardly from a peripheral region of a memory array.

5. A memory circuit architecture comprising:
a plurality of wordlines defining a longitudinal axis;
an array of memory cells addressable by at least one of the plurality of wordlines; and
a plurality of wordline driver cells disposed along a peripheral region of the array of memory cells, each of the plurality of wordline driver cells including:
a plurality of diffusion regions that form a plurality of wordline driver semiconductor switching devices,
each of the semiconductor switching devices having a channel width,
each of the semiconductor switching devices being arranged so that its respective channel width is perpendicular to the longitudinal axis of the plurality of wordlines.

6. The memory circuit architecture of claim 5, wherein each of the wordline driver cells comprises a plurality of wordline driver circuits that each selectively applies voltage to one of the wordlines, each of the wordline driver circuits including one or more of the semiconductor switching devices.

7. The memory circuit architecture of claim 6, wherein the one or more wordline driver semiconductor switching devices of each of the wordline driver circuits includes a p-type transistor disposed in an n-type diffusion region and two n-type transistors that are each disposed in a p-type diffusion region.

8. The memory circuit architecture of claim 7, wherein the p-type transistor is a p-type field effect transistor (pFET) and the two n-type transistors are n-type field effect transistors (nFETs).

9. The memory circuit architecture of claim 8, wherein the pFET and one of the two nFETs of each of the wordline driver circuits are each connected to the same wordline of the plurality of wordlines.

10. The memory circuit architecture of claim 7, wherein n-type diffusion regions within each of the driver cells are mutually spaced along a direction parallel to the wordlines according to a diffusion-to-diffusion rule, and wherein p-type diffusion regions within each of the driver cells are spaced from an outer edge of an n-type diffusion region by a sum-of-a-well rule and two diffusion-to-well rules.

11. The memory circuit architecture of claim 5, wherein a diffusion region width of each of the diffusion regions defines the respective channel width of each of the semiconductor switching devices disposed thereon.

12. The memory circuit architecture of claim 11, wherein each of the diffusion regions has a diffusion region length that is at least partially determined by a sum of gate lengths of the semiconductor switching devices disposed on each respective diffusion region.

13. The memory circuit architecture of claim 5, wherein the array of memory cells at least partially forms a Flash memory array.

14. The memory circuit architecture of claim 5, wherein the array of memory cells at least partially forms a dynamic random access memory (DRAM) array.

15. A peripheral circuit architecture for a memory array having a plurality of wordlines, the peripheral circuit architecture comprising:
a plurality of diffusion regions that form semiconductor switching devices;
a plurality of wordline driver semiconductor switching devices, each of the wordline driver semiconductor switching devices being formed in one of the diffusion regions and each of the wordline driver semiconductor switching devices having a respective channel width; and
a plurality of electrical conductor lines, each of the electrical conductor lines electrically connecting one or more of the plurality of wordline driver semiconductor switching devices to one of the plurality of wordlines in the memory array, the channel width of each of the wordline driver semiconductor switching devices being disposed substantially perpendicular to a longitudinal axis of at least one of the wordlines in the memory array.

16. The peripheral circuit architecture of claim 15, wherein the plurality of wordline driver semiconductor switching devices and the electrical conductor lines form at least one wordline driver cell, the wordline driver cell containing a plurality of wordline driver circuits that supply voltage to at least a portion of the wordlines of the memory array.

17. The peripheral circuit architecture of claim 16, wherein the wordline driver semiconductor switching devices are field effect transistors and each of the wordline driver circuits includes a p-type field effect transistor (pFET) disposed in an n-type diffusion region and two n-type field effect transistors (nFETs) that are each disposed in a p-type diffusion region.

18. The peripheral circuit architecture of claim 17, wherein n-type diffusion regions within a driver circuit cell are mutually spaced along a direction parallel to the wordlines according to a diffusion-to-diffusion rule, and wherein a p-type diffusion region is spaced from an edge of an n-type diffusion region furthest from the wordlines by a sum of a well rule and two diffusion-to-well rules.

19. The peripheral circuit architecture of claim 18, wherein a pFET and an nFET in each driver circuit of each of the wordline driver cells are each connected to a global wordline power line of the respective wordline driver cell.

20. The peripheral circuit architecture of claim 17, wherein the n-type and p-type diffusion regions each have a diffusion region length that is at least partially determined from a sum of gate lengths of the transistors disposed therein.

21. The peripheral circuit architecture of claim 17, wherein a pFET and an nFET of each of the wordline driver circuits are each connected to the same one of the wordlines of the memory array.

22. The peripheral circuit architecture of claim 16, wherein the wordline driver cell comprises four wordline driver circuits, each wordline driver circuit being connected to a different one of the plurality of wordlines of the memory array.

23. The peripheral circuit of claim 22, wherein the wordline driver cell comprises a p-type diffusion region separated from a nearest neighbor n-type diffusion region of the wordline driver cell by a distance defined by a sum-of-a-well rule and two diffusion-to-well rules.

24. The peripheral circuit architecture of claim 22, wherein each of the wordline driver cells comprises two nearest neighbor n-type diffusion regions, each n-type diffusion region used to form two p-type transistors of two respective wordline driver circuits, and wherein a mutual separation between adjacent n-type diffusion regions in a direction parallel to the wordlines is defined by a diffusion-to-diffusion ground rule.

25. The peripheral circuit architecture of claim 15, wherein the memory array at least partially forms a Flash memory array.

26. The peripheral circuit architecture of claim 15, wherein the memory array at least partially forms a dynamic random access memory (DRAM) array.

27. The peripheral circuit architecture of claim 15, wherein each diffusion region width defines the respective channel width of each of the wordline driver semiconductor switching devices.

28. A wordline driver cell coupled to a plurality of wordlines, the wordline driver cell comprising:
at least one p-type diffusion region arranged to extend outwardly from a portion of a peripheral region of a memory array;
at least one n-type diffusion region arranged to extend outwardly from a portion of a peripheral region of a memory array;
at least one p-type wordline driver transistor having source/drain regions formed within the at least one n-type diffusion region and having a gate channel width arranged perpendicular to a longitudinal axis of the plurality of wordlines;
at least one n-type wordline driver transistor having source/drain regions formed within the at least one p-type diffusion region and having a gate channel width arranged perpendicular to the longitudinal axis of the plurality of wordlines; and
at least one wordline driver circuit formed by coupling the p-type wordline driver transistor and the n-type wordline driver transistor to one of the plurality of wordlines coupled to the wordline driver cell.
